(19) United States
(12) Patent Application Publication
(10) Pub. No.: US 2012/0020140 A1
(43) Pub. Date: Jan. 26, 2012

(54) RESISTIVE MEMORY CELL AND OPERATION THEREOF, AND RESISTIVE MEMORY AND OPERATION AND FABRICATION THEREOF

(75) Inventor: Frederick T. Chen, Hsinchu County (TW)

(73) Assignee: INDUSTRIAL TECHNOLOGY RESEARCH INSTITUTE, Hsinchu (TW)

(21) Appl. No.: 12/839,411

(22) Filed: Jul. 20, 2010

(51) Int. Cl. G11C 11/00; H01L 45/00; H01L 21/8239

(52) U.S. Cl. 365/148; 438/3; 257/4; 257/E21.645; 257/E45.001; 365/145

(57) ABSTRACT

A resistive memory cell is described, including a first electrode, a high-resistance ferroelectric material layer and a second electrode. The ferroelectric material layer has a first interface with the first electrode and has a second interface with the second electrode, wherein the second interface is not parallel with the first interface. A method of operating the resistive memory cell is also described, including applying between the first electrode and the second electrode a series of voltages, which has positive polarity and negative polarity alternately and has descending absolute values, to form in the ferroelectric material layer at least one domain wall with low resistance.

### BACKGROUND

1. Technical Field

This disclosure relates to a resistive memory cell, a method of operating the resistive memory cell, a resistive memory based on the resistive memory cells, a method of operating the restive memory, and a method of fabricating the restive memory.

2. Description of Related Art

Current storage-class memories can be divided into several types: hard disk drives (HDD), CD-RW discs, and solid state drives (SSD). HDD technology is very robust and has the lowest cost per bit. However, both HDD and CD-RW require mechanical parts for rotation, which add weight to any electronic device using them. SSD technology is based on NAND flash memory, which is based on charge storage and can store more than one bit per cell. Current flash memory leading edge is 32 nm and 3 bits per cell. However, such memory is limited in the cyclability (˜10⁵ cycles at most), lacks random access and has high power consumption (>10V, 10 μA).

Resistive random access memory (RRAM or ReRAM) is a recently investigated memory technology, which provides both random access and lower power consumption and even has higher cyclability. However, its key limitation is the bit density, which is largely due to the three terminals placed side by side for standard MOSFET operation. Methods for increasing the bit density of RRAM include using multi-level operation (MLC) and using a diode as a selector. MLC is already used in NAND flash and allows more bits to be processed and stored within the same cell size, while a vertically conducting diode reduces the cell size (to the same physical size as NAND flash memory), since there are no side by side terminals.

MLC capability for RRAM is currently difficult to achieve, although 2- to 3-bit operation has been shown, because the resistance distribution of each resistance state is very wide due to many natural variations in the conducting path (“filament”) network. Further, each resistance state requires different power levels (SET current or RESET voltage) to be reached. Hence, the bit capacity can only be increased at the cost of enlarging the driving transistor or diode to allow larger SET current or RESET voltage, for example. As a result, the bit density and the power consumption issue cannot be simultaneously improved.

On the other hand, J. Seidel et al., Nat. Mat. Vol. 8, 229 (2009) have reported that domain walls in BiFeO₃, which has a bulk resistivity usually in the order of 10⁶ ohm·m, can possess resistivities in the order of 1-10 ohm·m. The domain walls can be induced by opposing-polarity voltage pulses (V. Dierolf et al., Phys. Stat. Sol. 204, 690 (2007)). When a voltage pulse is applied between two electrodes, the electric field between the electrodes causes nucleation of small domains with the polarization matching the field orientation. This is followed by growth at a velocity dependent on the field strength.

### SUMMARY OF THE DISCLOSURE

This disclosure provides a resistive memory cell, which utilizes formation of conductive domain wall(s) in high-resistance ferroelectric material to store data.

This disclosure also provides a method of operating the resistive memory cell of this disclosure.

This disclosure further provides a resistive memory, which is based on a plurality of the resistive memory cells of this disclosure.

This disclosure also provides a method of operating a resistive memory that is based on a plurality of the resistive memory cells of this disclosure.

This disclosure also provides a method of fabricating a resistive memory that is based on a plurality of the resistive memory cells of this disclosure.

The resistive memory cell includes a first electrode, a ferroelectric material layer having a first interface with the first electrode, and a second electrode having a second interface with the ferroelectric material layer. The second interface is not parallel with the first interface.

In an embodiment, the first interface is substantially perpendicular to the second interface. The ferroelectric material layer and the second electrode may be arranged in parallel over the first electrode. When the second electrode partially overlaps the first electrode, the resistive memory cell may further include an insulating layer disposed between the first electrode and the second electrode.

In an embodiment, the first electrode and the second electrode both contact the ferroelectric material layer. The first electrode may be coupled to a word line via a field-effect transistor or a diode. The diode may be a Schottky diode or a tunneling diode. The second electrode may be a portion of a bit line.

In an embodiment, the resistive memory cell further includes a tunnel layer disposed at the first interface and the second interface. The first electrode may be a portion of a word line. The second electrode may be a portion of a bit line.

In an embodiment, the ferroelectric material layer comprises BiFeO₃.

The resistive memory of this disclosure includes a plurality of memory cells arranged in rows and columns, a plurality of word lines and a plurality of bit lines. Each memory cell comprises a bottom electrode, a ferroelectric material layer over the bottom electrode and a top electrode beside the ferroelectric material layer. Each word line is coupled with the bottom electrodes of a row of memory cells. Each bit line is coupled with the top electrodes of a column of memory cells.

In an embodiment, the top electrode partially overlaps the bottom electrode in each memory cell, and each memory cell further includes an insulating layer between the bottom electrode and the top electrode.

In an embodiment, in each memory cell, the bottom electrode and the top electrode both contact the ferroelectric material layer. The bottom electrode of each memory cell may be coupled to a corresponding word line via a field-effect transistor or a diode. When the field-effect transistor includes a gate electrode and two source/drain regions, the gate electrode is coupled to the corresponding word line and one of the two source/drain regions coupled to the bottom electrode of the memory cell, the resistive memory may further include a plurality of source lines, each of which is coupled with the other of the two source/drain regions of each of the field-effect transistors coupled with a row of memory cells. The diode may be a Schottky diode or a tunneling diode.

In an embodiment, each memory cell further includes a tunnel layer disposed between the bottom electrode and the ferroelectric material layer and between the top electrode and the ferroelectric material layer. The bottom electrode of each memory cell may be a portion of a corresponding word line. The top electrode of each memory cell may be a portion of a corresponding bit line.

The method of operating a resistive memory cell of this disclosure is described as follows. A 1^{st} voltage is applied between the first electrode and the second electrode to form in the ferroelectric material layer a 1^{st} domain having a first polarity. Between the first electrode and the second electrode is applied a 2^{nd} voltage that is opposite in polarity and smaller in absolute value as compared to the 1^{st} voltage to form, in the 1^{st} domain, a 2^{nd} domain that is opposite in polarity and smaller in volume as compared to the 1^{st} domain, and a conductive domain wall between the 1^{st} domain and the 2^{nd} domain.

In an MLC operation, the above method further includes the following step. Between the first electrode and the second electrode are applied 3^{rd} to k-th (3≦k≦2ⁿ, n≧2) voltages sequentially, wherein the i-th (3≦i≦k) voltage is opposite in polarity and smaller in absolute value as compared with the (i−1)-th voltage to form, in the (i−1)-th domain, an i-th domain that is opposite in polarity and smaller in volume as compared to the (i−1)-th domain, and a conductive domain wall between the (i−1)-th domain and the i-th domain.

The method of operating a resistive memory of this disclosure is described as follows. A 1^{st} pair of biases are applied to a selected word line and a selected bit line coupled to a selected memory cell to induce a 1^{st} voltage between the bottom electrode and the top electrode of the selected memory cell and form, in the ferroelectric material layer of the selected memory cell, a 1^{st} domain having a first polarity. A 2^{nd} pair of biases are applied to the selected word line and the selected bit line to induce, between the bottom electrode and the top electrode of the selected memory cell, a 2^{nd}, voltage that is opposite in polarity and smaller in absolute value as compared with the 1^{st} voltage and form, in the 1^{st} domain, a 2^{nd} domain that is opposite in polarity and smaller in volume as compared with the 1^{st} domain, and a conductive domain wall between the 1^{st} domain and the 2^{nd} domain.

In an MLC operation, the above method further includes the following step. Third to k-th (3≦k≦2ⁿ, n≧2) pairs of biases are sequentially applied to the selected word line and the selected bit line to sequentially induce 3^{rd} to k-th voltages between the first electrode and the second electrode of the selected memory cell, wherein the i-th (3≦i≦k) voltage is opposite in polarity and smaller in absolute value as compared with the (i−1)-th voltage to form, in the (i−1)-th domain, an i-th domain that is opposite in polarity and smaller in volume as compared to the (i−1)-th domain, and a conductive domain wall between the (i−1)-th domain and the i-th domain.

In an embodiment, the bottom electrode of each memory cell is coupled to a corresponding word line via a field-effect transistor that includes a gate electrode coupled to the corresponding word line and two source/drain regions, one of which is coupled to the bottom electrode of the memory cell. The resistive memory further includes a plurality of source lines each coupled to the other of the two source/drain regions of each of the field-effect transistors coupled to a row of memory cells. In the step of applying the j-th (j=1 or 2) pair of biases to the selected word line and the selected bit line, the bias applied to the selected word line is a gate bias that turn on a channel under the gate electrode of the field-effect transistor coupled to the selected memory cell, the bias applied to the selected bit line is a j-th bias, and a reference bias is applied to unselected bit lines and the source lines, wherein the j-th bias minus the reference bias is equal to the j-th voltage.

In an MLC operation, the above embodiment further includes the following step. While the selected word line is applied with the gate bias and the unselected bit lines and the source lines applied with the reference bias, 3^{rd} to k-th (3≦k≦2ⁿ, n≧2) biases are sequentially applied to the selected bit line. The i-th (3≦i≦k) bias minus the reference bias is equal to an i-th voltage, and the i-th voltage is opposite in polarity and smaller in absolute value as compared with the (i−1)-th voltage to form, in the (i−1)-th domain, an i-th domain that is opposite in polarity and smaller in volume as compared to the (i−1)-th domain, and a conductive domain wall between the (i−1)-th domain and the i-th domain.

The method of fabricating a resistive memory of this disclosure is described as follows. A plurality of word lines extending in a first direction is formed over a substrate. A plurality of bit lines extending in a second direction different from the first direction is formed over the word lines. A ferroelectric material layer is formed at least between the bit lines. The ferroelectric material layer is coupled with the word lines and the bit lines, and a portion thereof beside an overlap area of a word line and a bit line acts as a data storage region of a memory cell.

In an embodiment, the above method further includes forming over the substrate a substantially conformal tunnel layer before the ferroelectric material layer is formed. The tunnel layer may include silicon oxide or aluminum oxide.

In an embodiment, each word line has a first insulating layer thereon, the step of forming the bit lines comprises forming a plurality of linear second insulating layers and forming two bit lines on two sidewalls of each second insulating layer, and the bit lines are separated from the word lines by the first insulating layer. The method further includes, before the ferroelectric material layer is formed, removing portions of the first insulating layer using the second insulating layers and the bit lines as a mask, and forming over the substrate a substantially conformal first tunnel layer. The ferroelectric material layer may fill up the gaps between the bit lines. The first tunnel layer may include silicon oxide or aluminum oxide. The step of forming two bit lines on the two sidewalls of each second insulating layer may include forming over the substrate a substantially conformal conductive layer, and performing anisotropic etching to the conductive layer. The method may further include, after the ferroelectric material layer is formed, forming on the ferroelectric material layer a second tunnel layer; and forming on the second tunnel layer a plurality of upper-level word lines extending in the first direction.

In an embodiment, the ferroelectric material includes BiFeO₃.

In an embodiment, the ferroelectric material layer is formed through metal-organic chemical vapor deposition (MOCVD).

Since the resistive memory cell is written by altering the direction of the electric field to form one or more domain walls, rather than by phase change as in the prior art, the cell current is greatly reduced to much reduce the power consumption. In addition, a resistive memory cell of this disclosure with a linewidth of 32 nm can easily store up to three bits of data, as described later, and is therefore competitive with the leading edge NAND flash memory mentioned above in the bit density.

In order to make the aforementioned and other objects, features and advantages of this disclosure comprehensible, a preferred embodiment accompanied with figures is described in detail below.

### BRIEF DESCRIPTION OF THE DRAWINGS

FIG. 1A illustrates a perspective view of a resistive memory cell according to an embodiment of this disclosure, and FIG. 1B illustrates the I-I′ cross-sectional view of the same.

FIG. 2A illustrates a perspective view of the resistive memory cell of the above embodiment and a field-effect transistor coupled thereto for control, and FIG. 2B illustrates the I-I′ cross-sectional view of the same.

FIG. 3A illustrates a perspective view of a resistive memory cell according to another embodiment of this disclosure, and FIG. 3B illustrates the I-I′ cross-sectional view of the same.

FIGS. 4A and 4B illustrate cross-sectional views of a resistive memory cell and a control device coupled thereto according to two other embodiments of this disclosure.

FIGS. 5A and 5B illustrate the electric field distribution under application of a voltage in a resistive memory cell according to an embodiment of this disclosure.

FIGS. 6A-6F illustrate a method of operating a resistive memory according to an embodiment of this disclosure.

FIG. 7 is a circuit diagram of a resistive memory according to an embodiment of this disclosure.

FIG. 8 is a circuit diagram of a resistive memory according to another embodiment of this disclosure.

FIGS. 9A-9D illustrate, in a cross-sectional view, a method of fabricating a resistive memory according to an embodiment of this disclosure, and FIGS. 9B′ and 9D′ are top views corresponding to FIGS. 9B and 9D, respectively.

### DESCRIPTION OF EMBODIMENTS

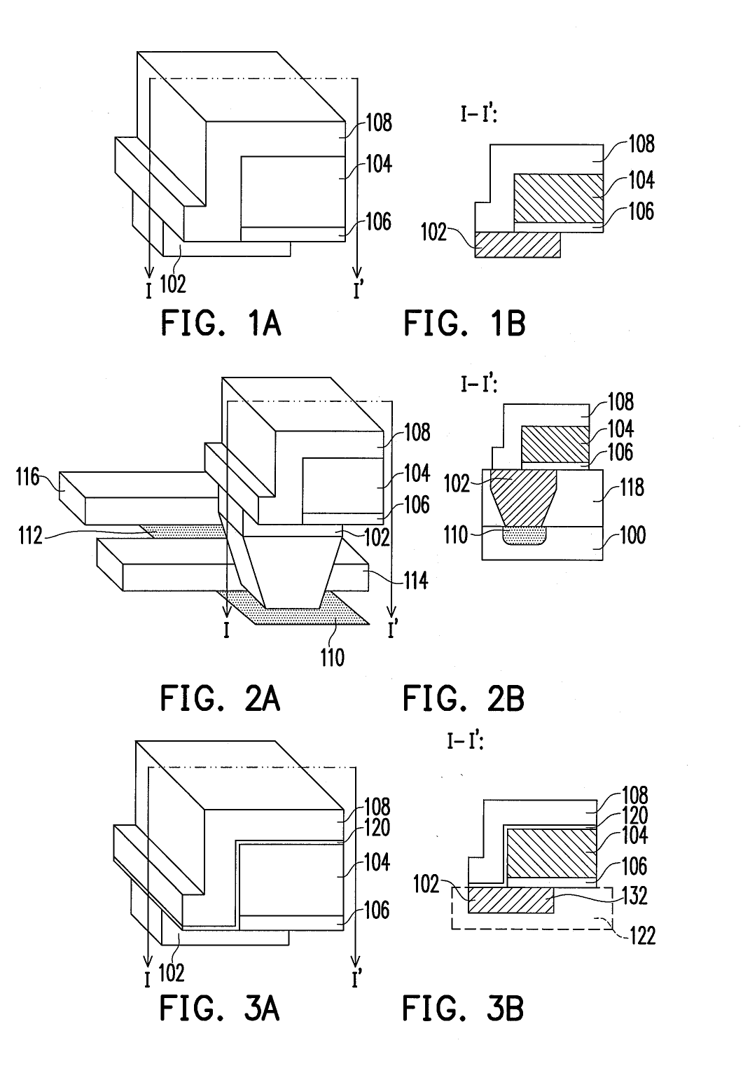

FIG. 1A illustrates a perspective view of a resistive memory cell according to an embodiment of this disclosure, and FIG. 1B illustrates the I-I′ cross-sectional view of the same.

Referring to FIG. 1A/B, the resistive memory cell includes a bottom electrode 102, a top electrode 104, an insulating layer 106 and a ferroelectric material layer 108. The top electrode 104 partially overlaps the bottom electrode 102, and is isolated from the latter by the insulating layer 106. The ferroelectric material layer 108 is disposed over the bottom electrode 102 and beside the top electrode 104, and contacts both of the bottom electrode 102 and the top electrode 104. The first interface between the ferroelectric material layer 108 and the bottom electrode 102 is substantially perpendicular to the second interface between the ferroelectric material layer 108 and the top electrode 104, so a non-uniform electric field is induced in the ferroelectric material layer 108 when a voltage is applied between the bottom electrode 102 and the top electrode 104. In addition, to meet the requirement of some fabricating process, the ferroelectric material layer 108 may have an extra portion covering the top electrode 104, as shown in FIG. 1A/B, which does not affect normal operations of the cell.

The bottom electrode 102 may include W, TiN, Ti, Pt or Al, and may have a thickness of 10-100 nm. The top electrode 104 may include TiN, W, TiW or Ti, and may have a thickness of 10-100 nm. The insulating layer 106 may include silicon nitride or SiO₂, and may have a thickness of 10-300 nm. The ferroelectric material layer 108 may include BiFeO₃ or BaTiO3, and may have a thickness of 5-25 nm.

BiFeO3 is an attractive ferroelectric material to be used, for 1) back-switching (spontaneous reversing of domain polarization in zero field) is not an issue as in the case of lithium niobate (J. Wang et al., Science 299, 1719 (2003)) and 2) the domain walls act as low resistance conduction paths separating insulating domains. Seidel et al. have indicated that for polarization orientation differences less than 90°, the domain walls are not conductive, while for polarization orientation differences more than 90°, the domain walls are conductive.

The top electrode 104 of the above resistive memory cell may be connected to a bit line or be a portion of a bit line, and the bottom electrode 102 may be coupled to a word line in the memory array via a control device. The control device may be a field-effect transistor or a diode. FIG. 2A illustrates a perspective view of the resistive memory cell of the above embodiment and a field-effect transistor coupled thereto as a control device, and FIG. 2B illustrates the I-I′ cross-sectional view of the same.

Referring to FIG. 2A/B, the bottom electrode 102 of the resistive memory cell is coupled to one source/drain (S/D) region 110 of the field-effect transistor. The other S/D region 112 of the transistor is separated from the S/D region 110 by a gate electrode as a portion of a word line 114, and is electrically connected with a source line 116. The S/D regions 110 and 112 are disposed in a semiconductor substrate 100, and the bottom electrode 102 disposed in an inter-layer dielectric (ILD) layer 118. Since the fabrications of the field-effect transistor and the source line 116 are known to one of ordinary skill in the art, their descriptions are omitted here.

In another embodiment of this disclosure, no control device is included to control the memory cell, but a tunnel layer is inserted between the ferroelectric material layer 108 and the bottom electrode 102 and between the ferroelectric material layer 108 and the top electrode 104. FIG. 3A illustrates a perspective view of such resistive memory cell, and FIG. 3B illustrates the I-I′ cross-sectional view of the same. The tunnel layer 120 allows larger current when the voltage is higher than a certain value (e.g., V), and thus also has a control effect. The tunnel layer 120 may include silicon oxide or aluminum oxide, and may have a thickness of 5-20 angstroms usually. In this embodiment, the top electrode 104 may be a portion of a bit line, and the bottom electrode 104 may be a portion of a word line.

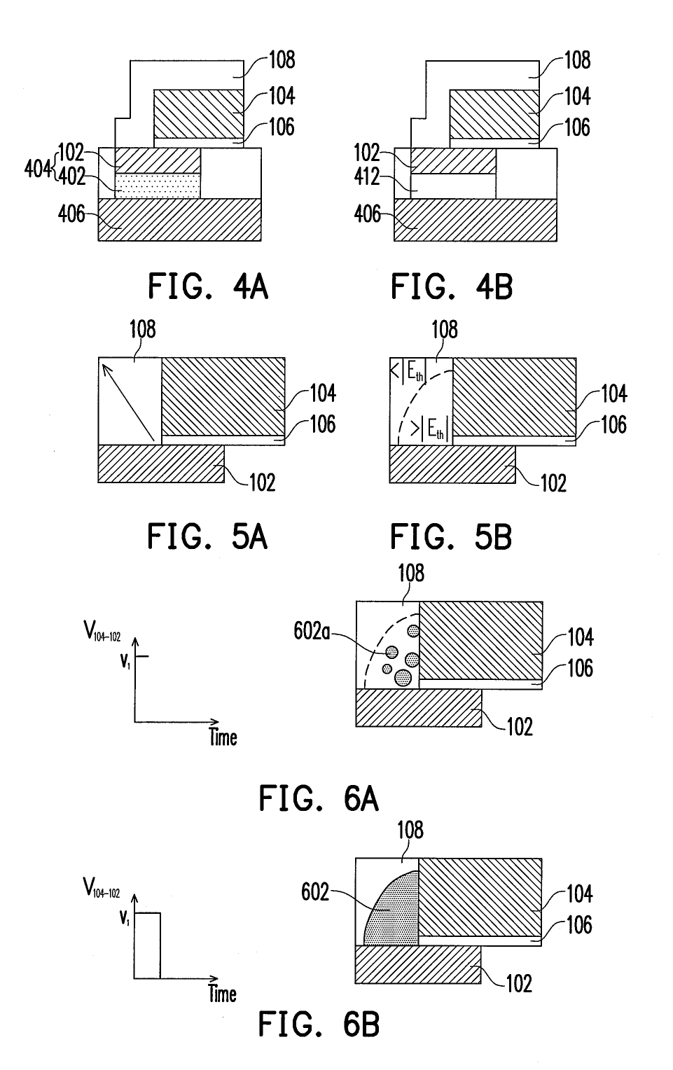

FIGS. 4A and 4B illustrate cross-sectional views of a resistive memory cell and a control device coupled thereto according to two other embodiments of this disclosure.

Referring to FIG. 4A, the bottom electrode 102 of the resistive memory cell of this embodiment is connected to a doped silicon layer 402 to form a Schottky diode 404 having a low breakdown voltage. The doped silicon layer 402 contacts a word line 406 at the bottom thereof, so that the resistive memory cell is coupled to the word line 406 via the Schottky diode 404. The doped silicon layer 402 may be an n-doped polysilicon layer. The doped silicon layer 402 may have a dopant concentration within the range of 10¹⁸-10²¹/cm³, and may have a thickness of 10-200 nm.

Referring to FIG. 4B, the bottom electrode 102 of the resistive memory cell of this embodiment is connected to a tunneling barrier (or tunneling diode) 412. The tunneling barrier 412 contacts a word line 406 at the bottom thereof, so that the resistive memory cell is coupled to the word line 406 via the tunneling barrier 412. The tunneling barrier 412 may include aluminum oxide, titanium oxide or tantalum oxide, and may have a thickness of 1-30 nm.

A method of operating of the resistive memory cell of this disclosure is described next. FIGS. 5A and 5B illustrate the electric field distribution under application of a voltage in a resistive memory cell according to an embodiment of this disclosure.

Referring to FIG. 5A/B, when there is a voltage between the bottom electrode 102 and the top electrode 104, the electric field strength in the ferroelectric material layer 108 decreases roughly in the direction of the arrow in FIG. 5A, so that the electric field strength in a certain region is larger than the threshold value |Eₜₕ|, as indicated by the dash line in FIG. 5B. The polarity of the ferroelectric material in the certain region will match the direction of the electric field after the voltage is applied for a certain period of time.

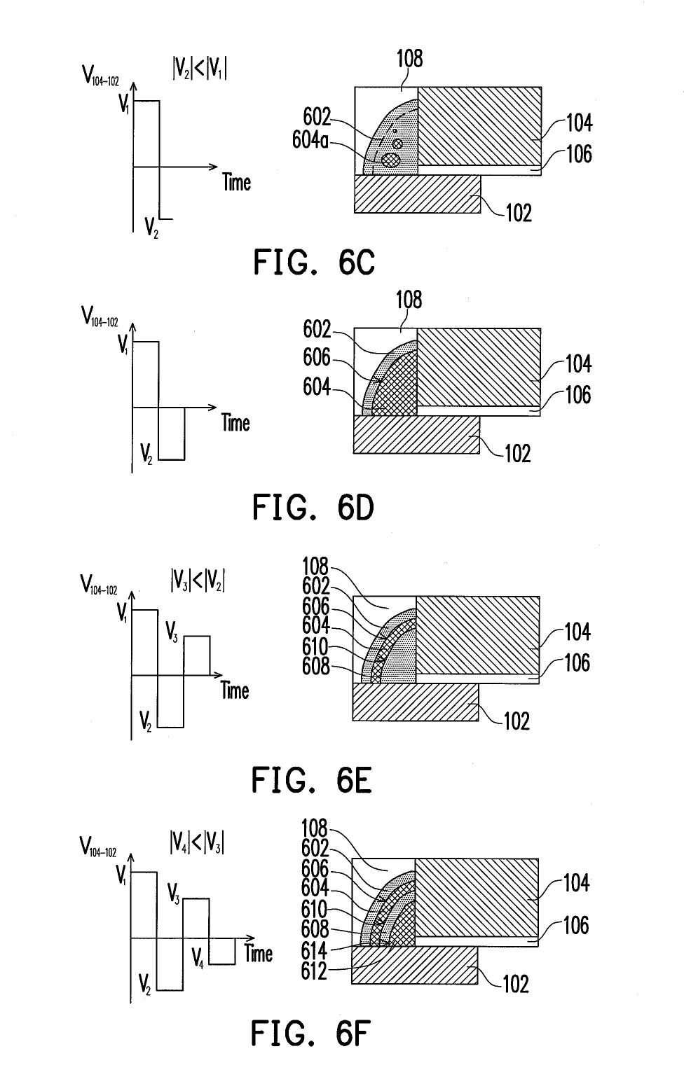

FIGS. 6A-6F illustrate a method of operating a resistive memory according to an embodiment of this disclosure, wherein V₁₀₄₋₁₀₂ is the value of the bias applied to the top electrode 104 minus the bias applied to the bottom electrode 102.

Referring to FIGS. 6A-6B, a voltage V₁ is applied between the bottom electrode 102 and the top electrode 104. Small domains 602a with polarity matching the electric field direction are first formed in the region with electric field strength larger than |Eₜₕ| in the ferroelectric material layer 108, and the entire region will become one domain 602 with polarity matching the electric field direction after a period of time.

Referring to FIGS. 6C-6D, a voltage V₂ that is opposite in polarity and smaller in the absolute value as compared to V₁ is applied between the bottom electrode 102 and the top electrode 104. Since the absolute value of V₂ is smaller than that of V₁, at this moment the region with electric field strength larger than |Eₜₕ| in the ferroelectric material layer 108 is smaller as compared to the case when V₁ is applied. Therefore, small domains 604a with polarity matching the direction of the electric field caused by V₂ are first formed in the region with electric field strength larger than |Eₜₕ| in the domain 602, and after a period of time, the entire region becomes one domain 604 that is smaller than the domain 602 and has polarity matching the direction of the electric field caused by V₂. Since the polarity of V₂ is opposite to that of V₁, the polarity of the domain 604 is opposite to that of the larger domain 602 so that a low-resistance domain wall 606 is formed between the domain 602 and the smaller domain 604.

When only one bit (“0” or “1”) is to be stored in one above resistive memory cell, the write process is stopped at the stage shown by FIG. 6B or 6D. For example, it is possible to designate the high-resistance state with the presence of the domain 602 only as the 0-state and the low-resistance state with the presence of the conductive domain wall 606 as the 1-state.

If more bits are to be stored in each memory cell, more conductive domain walls have to be formed. As shown in FIG. 6E, a voltage V₃ that is opposite in polarity and smaller in the absolute value as compared to V₂ is then applied between the bottom electrode 102 and the top electrode 104, so that a domain 608 is formed in the domain 604 with an opposite polarity and a smaller volume as compared to the domain 604. Thus, another conductive domain wall 610 is formed between the domain 604 and the domain 608, further lowering the resistance of the ferroelectric material layer 108. As shown in FIG. 6F, a voltage V₄ that is opposite in polarity and smaller in the absolute value as compared to V₃ is then applied between the bottom electrode 102 and the top electrode 104, so that a domain 612 is formed in the domain 608 with an opposite polarity and a smaller volume as compared to the domain 608. Thus, another conductive domain wall 614 is formed between the domain 608 and the domain 612, further lowering the resistance of the ferroelectric material layer 108.

When two bits (“00”, “01”, “10” or “11”) are to be stored in the memory cell, the write process is stopped at the stage shown by FIG. 6B, 6D, 6E or 6F. For example, it is possible to designate the high-resistance state with the presence of the domain 602 only as the 00-state, the low-resistance state with the presence of the one conductive domain wall 606 as the 01-state, the lower-resistance state with the presence of the two conductive domain walls 606 and 610 as the 10-state, and the lowest-resistance state with the presence of three conductive domain walls 606, 610 and 614 as the 11-state.

Accordingly, to store m bits (m>2) in each memory cell, at most 2^{m}−1 conductive domain walls have to be formed in a memory cell, which means that the above voltage application step with polarity reversing and absolute-value decrease has to be conducted 2^{m}−1 times at most for a memory cell. In a real practice, the minimal distance between two neighboring domain walls in a ferroelectric material layer 108 of BiFeO₃ is about 4 nm. When the width of the ferroelectric material layer 108 is 32 nm that corresponds to a process linewidth of 32 nm, seven (=2³−1) conductive domain walls can be formed in the ferroelectric material layer 108. Thus, the resistive memory cell can store up to three bits of data and is competitive with the leading edge of NAND flash memory in the bit density.

Moreover, to erase the resistive memory cell, it is possible to apply between the bottom electrode 102 and the top electrode 104 a voltage having an absolute value equal to or larger than that of V₁ for a certain period of time to eliminate the domain wall(s). The polarity of the erase voltage may be the same as or different from that of V₁. On the other hand, the above resistive memory cell can be read with the following steps. A low voltage (e.g., 0.1V) that does not damage the existing domain wall(s) and causes no new domain to form in the ferroelectric material layer 108 is applied between the bottom electrode 102 and the top electrode 104, and the storage state of the cell is determined from the magnitude of the cell current. The more conductive domain walls are in the ferroelectric material layer 108, the lower the resistance of the cell is, and the larger the cell current is.

Further, in each of the above operations of the resistance memory cell of this disclosure, the cell current is at the order of 1 nA so that the power consumption is greatly reduced to under 1 nW. The length of each voltage pulse is 0.1-100 μs, so the operation speed of the resistance memory cell is potentially high.

Moreover, though the two electrodes of the resistive memory cell in each of the above embodiments are arranged vertically, this disclosure is not limited thereto. The two electrodes may alternatively be arranged in parallel. Furthermore, though the first interface between the ferroelectric material layer and the first electrode is perpendicular to the second interface between the ferroelectric material layer and the second electrode in the above embodiments, this disclosure is not limited thereto. The angle between the first interface and the second interface may be larger or smaller than 90 degrees, if only the two are not parallel with each other and the resulting non-uniform electric field in the ferroelectric material layer allows at least one conductive domain wall to be formed.

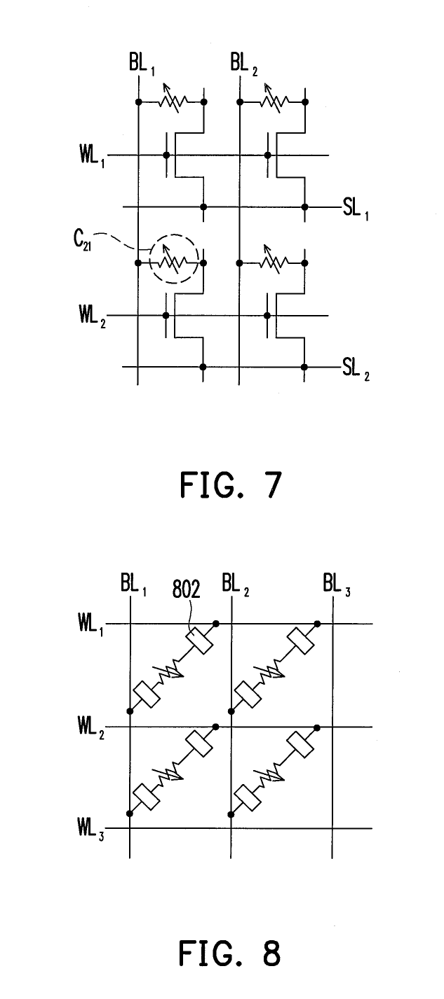

FIG. 7 is a circuit diagram of a resistive memory according to an embodiment of this disclosure. Referring to FIGS. 2A/B and 7, each variable resistor represents a resistive memory cell of this disclosure, of which the bottom electrode 102 is connected to one of the two S/D regions of a field-effect transistor. The resistive memory cells are arranged in rows and columns, so are the field-effect transistors for accessing the memory cells. The gate electrodes of a row of field-effect transistors are coupled to a word line WL, the top electrodes 104 of a column of resistive memory cells are coupled to a bit line BL, and the other S/D region of each of a row of field-effect transistors not coupled to resistive memory cells are coupled to a source line SL.

The method of operating a resistive memory according to an embodiment of this disclosure is described below, taking the operation of the memory cell C₂₁ coupled to the word line WL₂ and the bit line BL₁ as an example. The method mainly includes, in writing, erasing or reading, applying a proper bias to the selected word line WL₂ to turn on the channel of the field-effect transistor coupled to C₂₁, applying a constant reference bias (e.g., 0V) to the selected source line SL₂ coupled to the same field-effect transistor, and applying a bias higher or lower than the reference bias to the selected bit line BL₁ to create a positive or negative between the bottom electrode and the top electrode of C₂₁. The unselected word lines including WL₁ may be floated or applied with a bias (e.g., 0V) that does not turn on the channels of the transistors coupled thereto. The unselected bit lines including BL₂ and the unselected source lines including SL₁ may be floated or applied with the reference bias.

An exemplary bias configuration of the lines for writing or reading is provided in Table 1 below. The bias applied to the selected word line WL₂ in the read operation is higher than that in the write operation to obtain the effect of reducing the source-drain resistance. If a 3^{rd} domain that is opposite in polarity and smaller in volume as compared to the 2^{nd} domain is to be formed in the 2^{nd} domain and a 4^{th} domain that is opposite in polarity and smaller in volume as compared to the 3^{rd} domain is to be formed in the 3^{rd} domain, it is possible to sequentially apply, to the selected bit line BL₁, a voltage of 1.2 V that is opposite in the polarity and smaller in the absolute value as compared to −1.6 V, and a voltage of −0.8 V that is opposite in the polarity and smaller in the absolute value as compared to 1.2 V, while the biases applied to other lines are not changed.

TABLE 1

| | | WL₁ | WL₂ | BL₁ | BL₂ | SL₁ | SL₂ |
|---|---|---|---|---|---|---|---|
| Writing | Formation of | 0 V | 2 V | 2 V | 0 V | 0 V | 0 V |
| | 1^{st} domain | | | | | | |
| | Formation of | 0 V | 2 V | −1.6 V | 0 V | 0 V | 0 V |
| | smaller 2^{nd} | | | | | | |
| | domain with | | | | | | |
| | opposite | | | | | | |
| | polarity | | | | | | |

| | | | | | | |
|---|---|---|---|---|---|---|
| Reading | 0 V | 3.3 V | 0.1 V | 0 V | 0 V | 0 V |

FIG. 8 is a circuit diagram of a resistive memory according to another embodiment of this disclosure. Referring to FIGS. 3A/B and 8, each variable resistor represents a resistive memory cell of this disclosure, and the element 802 represents the tunnel layer 120 in FIGS. 3A/B. The resistive memory cells are arranged in rows and columns, wherein the bottom electrodes 102 of a row of memory cells are coupled to a word line WL, and the top electrodes 104 of a column of memory cells are coupled to a bit word line BL. Each bottom electrode 102 may be a portion of the corresponding word line, and each top electrode 104 may be a portion of the corresponding bit line.

Referring to FIG. 8 again, a selected memory cell in the resistive memory may be written by sequentially creating, between the selected word line and the selected bit line, a series of voltages that have positive polarity and negative polarity and descend in the absolute value, and floating the unselected word lines and the unselected bit lines. A selected memory cell may be read with the following operations. Between the selected word line and the selected bit line is applied a voltage that is high enough to overcome the energy barrier of the tunnel layer 802 and is also low enough so that the existing domain wall(s) is/are not damaged and no new domain is formed in the ferroelectric material layer. The unselected word lines and the unselected bit lines are floated.

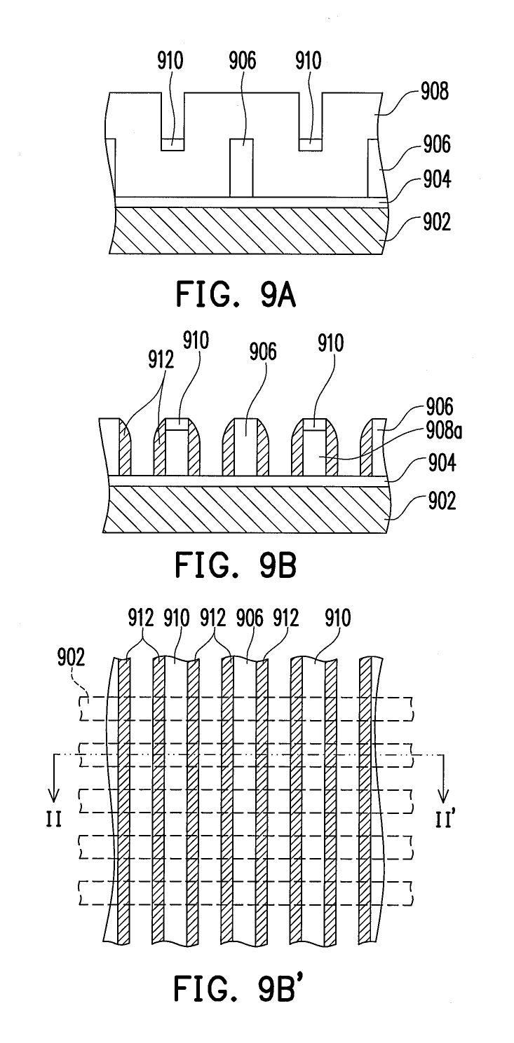

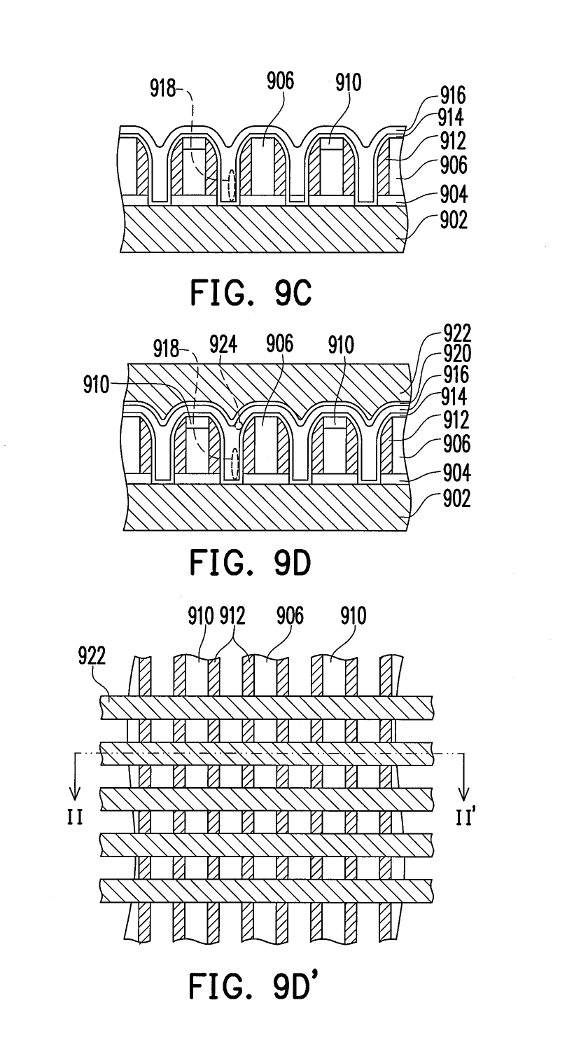

FIGS. 9A-9D illustrate, in a cross-sectional view, a method of fabricating a resistive memory according to an embodiment of this disclosure, and FIGS. 9B′ and 9D′ are top views corresponding to FIGS. 9B and 9D, respectively.

Referring to FIGS. 9A and 9B′, a plurality of word lines 902 extending in a first direction are formed over a substrate (not shown), wherein each word line 902 has an insulating layer 904 thereon. The word lines 902 may include doped polysilicon, W, Ti or TiN, and may have a thickness of 100-200 nm. The insulating layer 904 may include silicon nitride or silicon dioxide, and may have a thickness of 10-300 nm.

Then, insulating bars 906 extending in a second direction different from the first direction are formed over the insulating layer 904. The width of each insulating bar 906 is much smaller than the pitch of the insulating bars 906 to improve the accuracy of the pattern transfer. A substantially conformal insulating layer 908 is then formed on the insulating layer 904 and the insulating bars 906, and insulating bars 910 are filled in the gaps in the insulating layer 908 caused by the insulating bars 906 extending in the second direction. Hence, the insulating bars 910 also extend in the second direction.

Referring to FIG. 9B/B′, the insulating bars 910 are used as a mask to etch away the exposed insulating layer 908 to form insulating bars 910+908a also extending in the second direction. In the above process, the thickness of the insulating bars 910 and the etching selectivity between the insulating bars 910 and the insulating layer 908 has to be set properly such that the tops of the insulating bars 910+908a are coplanar with those of the insulating bars 906. The material of the insulating bars 906 may be SiO₂. The material of the insulating layer 908 may be carbon-doped silicon oxide (CDO). The material of the insulating bars 910 may be the same as that of the insulating bars 906. The thickness of the insulating bars 906 (or 910+908a) may be 100-300 nm.

Thereafter, two spacer-shaped bit lines 912 are formed on the two sidewalls of each insulating bar 906 or 910+908a. Because the insulating bars 906 and 910+908a extend in the second direction, the bit lines 912 also extend in the second direction. The bit lines 912 may be formed by forming a substantially conformal conductive layer over the substrate and then performing anisotropic etching to the conductive layer. The material of the bit lines may be TiN, W, TiW or Ti. The width of each bit line 912 may be 10-50 nm.

Referring to FIG. 9C, the insulating bars 906 and 910+908a and the bit lines 912 are used as a mask to etch away the exposed portions of the insulating layer 904 and expose portions of the word lines 902. A substantially conformal tunnel layer 914 and a ferroelectric material layer 916 are sequentially formed over the resulting structure. The tunnel layer 914 may include silicon oxide or aluminum oxide, may be formed through atomic layer deposition (ALD), and may have a thickness of 5-20 angstroms. The ferroelectric material layer 916 may include BiFeO₃ or BaTiO₃, has a sufficient thickness to fill up the gaps between the insulating bars 910+908a and the insulating bars 906, and may be formed through metal-organic chemical vapor deposition (MOCVD). For example, the recipe for depositing BiFeO₃ through MOCVD may include a reaction gas of Bi(CH₃COO)₃, a reaction gas flow rate of 5-50 l/h, a temperature of 300-700° C. and a pressure of 10-20 mbar.

Referring to FIGS. 9C and 9B′ and the precedent descriptions about the resistive memory cell of this disclosure, in the resulting structure, a portion of the ferroelectric material layer 916 at one side of the overlap region of a word line 902 and a bit line 912 is the data storage region 918 of a memory cell. The bottom electrode of the resistive memory cell is a portion of the word line 902, and the top electrode of the same is a portion of the bit line 912. The equivalent circuit diagram of the resistive memory is shown in FIG. 8.

Moreover, it is possible to form a second level of restive memory cells with the following steps. Referring to FIG. 9D/D′, a tunnel layer 920 and a plurality of upper-level word lines 922 are sequentially formed over the above resulting structure. The material, forming method and thickness of the tunnel layer 920 may be the same as those of the tunnel layer 914. The upper-level word lines 922 may include TiN, W, Ti, TiW or Al, and may have a thickness of 100-200 nm. In such a structure, a portion of the ferroelectric material layer 916 at one side of the overlap region of an upper-level word line 922 and a bit line 912 is the data storage region 924 of a memory cell of the second level. The bottom electrode of the second-level resistive memory cell is a portion of the bit line 912, and the top electrode of the same is a portion of the upper-level word line 922.

In summary, the resistive memory cell of this disclosure is written by altering the direction of the electric field to form one or more domain walls, rather than by phase change as in the prior art, so that the cell current is greatly reduced to the order of 1 nA and the power consumption much reduced to be less than 1 nW. Moreover, a resistive memory cell of this disclosure with a linewidth of 32 nm can easily store up to three bits of data, and is therefore competitive with the leading edge NAND flash memory in the bit density.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A resistive memory cell, comprising:
a first electrode;
a ferroelectric material layer, having a first interface with the first electrode; and
a second electrode, having a second interface with the ferroelectric material layer, wherein the second interface is not parallel with the first interface.

2. The resistive memory cell of claim 1, wherein the first interface is substantially perpendicular to the second interface.

3. The resistive memory cell of claim 2, wherein the ferroelectric material layer and the second electrode are arranged in parallel over the first electrode.

4. The resistive memory cell of claim 3, wherein the second electrode partially overlaps the first electrode, further comprising an insulating layer disposed between the first electrode and the second electrode.

5. The resistive memory cell of claim 1, wherein the first electrode and the second electrode both contact the ferroelectric material layer.

6. The resistive memory cell of claim 5, wherein the first electrode is coupled to a word line via a field-effect transistor or a diode.

7. The resistive memory cell of claim 6, wherein the diode comprises a Schottky diode or a tunneling diode.

8. The resistive memory cell of claim 6, wherein the second electrode is a portion of a bit line.

9. The resistive memory cell of claim 1, further comprising a tunnel layer disposed at the first interface and the second interface.

10. The resistive memory cell of claim 9, wherein the first electrode is a portion of a word line.

11. The resistive memory cell of claim 10, wherein the second electrode is a portion of a bit line.

12. The resistive memory cell of claim 1, wherein the ferroelectric material layer comprises BiFeO₃.

13. A resistive memory, comprising:
a plurality of memory cells arranged in rows and columns, wherein each memory cell comprises a bottom electrode, a ferroelectric material layer over the bottom electrode and a top electrode beside the ferroelectric material layer;
a plurality of word lines, each coupled with the bottom electrodes of a row of memory cells; and
a plurality of bit lines, each coupled with the top electrodes of a column of memory cells.

14. The resistive memory of claim 13, wherein the top electrode partially overlaps the bottom electrode in each memory cell, and each memory cell further comprises an insulating layer between the bottom electrode and the top electrode.

15. The resistive memory of claim 13, wherein in each memory cell, the bottom electrode and the top electrode both contact the ferroelectric material layer.

16. The resistive memory of claim 15, wherein the bottom electrode of each memory cell is coupled to a corresponding word line via a field-effect transistor or a diode.

17. The resistive memory of claim 16, wherein the field-effect transistor includes a gate electrode and two source/drain regions, the gate electrode is coupled to the corresponding word line and one of the two source/drain regions coupled to the bottom electrode of the memory cell, further comprises:
a plurality of source lines, each coupled with the other of the two source/drain regions of each of the field-effect transistors coupled with a row of memory cells.

18. The resistive memory of claim 16, wherein the diode comprises a Schottky diode or a tunneling diode.

19. The resistive memory of claim 13, wherein each memory cell further comprises a tunnel layer disposed between the bottom electrode and the ferroelectric material layer and between the top electrode and the ferroelectric material layer.

20. The resistive memory of claim 19, wherein the bottom electrode of each memory cell is a portion of a corresponding word line.

21. The resistive memory of claim 13, wherein the top electrode of each memory cell is a portion of a corresponding bit line.

22. The resistive memory of claim 13, wherein the ferroelectric material layer comprises BiFeO₃.

23. A method of operating a resistive memory cell that comprises a first electrode, a ferroelectric material layer having a first interface with the first electrode, and a second electrode having a second interface not parallel with the first interface with the ferroelectric material layer, comprising:
applying a 1^{st} voltage between the first electrode and the second electrode to form in the ferroelectric material layer a 1^{st} domain having a first polarity; and
applying between the first electrode and the second electrode a 2^{nd} voltage that is opposite in polarity and smaller in absolute value as compared to the 1^{st} voltage to form, in the 1^{st} domain, a 2^{nd} domain that is opposite in polarity and smaller in volume as compared to the 1^{st} domain, and a conductive domain wall between the 1^{st} domain and the 2^{nd} domain.

24. The method of claim 23, further comprising:
applying between the first electrode and the second electrode 3^{rd} to k-th (3≦k≦2ⁿ, n≧2) voltages sequentially, wherein the i-th (3≦i≦k) voltage is opposite in polarity and smaller in absolute value as compared with the (i−1)-th voltage to form, in the (i−1)-th domain, an i-th domain that is opposite in polarity and smaller in volume as compared to the (i−1)-th domain, and a conductive domain wall between the (i−1)-th domain and the i-th domain.

25. The method of claim 23, wherein the first interface is substantially perpendicular to the second interface.

26. A method of operating a resistive memory,
the resistive memory comprising:
a plurality of memory cells arranged in rows and columns, wherein each memory cell comprises a bottom electrode, a ferroelectric material layer over the bottom electrode and a top electrode beside the ferroelectric material layer;
a plurality of word lines, each coupled with the bottom electrodes of a row of memory cells; and
a plurality of bit lines, each coupled with the top electrodes of a column of memory cells,
and the method comprising:
applying a 1^{st} pair of biases to a selected word line and a selected bit line coupled to a selected memory cell to induce a 1^{st} voltage between the bottom electrode and the top electrode of the selected memory cell and form, in the ferroelectric material layer of the selected memory cell, a 1^{st} domain having a first polarity; and
applying a 2^{nd} pair of biases to the selected word line and the selected bit line to induce, between the bottom electrode and the top electrode of the selected memory cell, a 2^{nd} voltage that is opposite in polarity and smaller in absolute value as compared with the 1^{st} voltage and form, in the 1^{st} domain, a 2^{nd} domain that is opposite in polarity and smaller in volume as compared with the 1^{st} domain, and a conductive domain wall between the 1^{st} domain and the 2^{nd} domain.

27. The method of claim 26, further comprising:
sequentially applying 3^{rd} to k-th (3≦k≦2ⁿ, n≧2) pairs of biases to the selected word line and the selected bit line to sequentially induce 3^{rd} to k-th voltages between the first electrode and the second electrode of the selected memory cell, wherein the i-th (3≦i≦k) voltage is opposite in polarity and smaller in absolute value as compared with the (i−1)-th voltage to form, in the (i−1)-th domain, an i-th domain that is opposite in polarity and smaller in volume as compared to the (i−1)-th domain, and a conductive domain wall between the (i−1)-th domain and the i-th domain.

28. The method of claim 26, wherein
the bottom electrode of each memory cell is coupled to a corresponding word line via a field-effect transistor, wherein the field-effect transistor comprises a gate electrode coupled to the corresponding word line, and two source/drain regions one of which is coupled to the bottom electrode of the memory cell,
the resistive memory further comprises a plurality of source lines each coupled to the other of the two source/drain regions of each of the field-effect transistors coupled to a row of memory cells, and
in the step of applying the j-th (j=1 or 2) pair of biases to the selected word line and the selected bit line, the bias applied to the selected word line is a gate bias that turn on a channel under the gate electrode of the field-effect transistor coupled to the selected memory cell, the bias applied to the selected bit line is a j-th bias, and a reference bias is applied to unselected bit lines and the source lines, wherein the j-th bias minus the reference bias is equal to the j-th voltage.

29. The method of claim 28, further comprising:
while the selected word line is applied with the gate bias and the unselected bit lines and the source lines applied with the reference bias, sequentially applying 3^{rd} to k-th (3≦k≦2ⁿ, n≧2) biases to the selected bit line, wherein the i-th (3≦i≦k) bias minus the reference bias is equal to an i-th voltage, and the i-th voltage is opposite in polarity and smaller in absolute value as compared with the (i−1)-th voltage to form, in the (i−1)-th domain, an i-th domain that is opposite in polarity and smaller in volume as compared to the (i−1)-th domain, and a conductive domain wall between the (i−1)-th domain and the i-th domain.

30. A method of fabricating a resistive memory, comprising:
forming over a substrate a plurality of word lines extending in a first direction;
forming over the word lines a plurality of bit lines extending in a second direction different from the first direction; and
forming a ferroelectric material layer at least between the bit lines, wherein the ferroelectric material layer is coupled with the word lines and the bit lines, and a portion of the ferroelectric material layer beside an overlap area of a word line and a bit line acts as a data storage region of a memory cell.

31. The method of claim 30, further comprising: forming over the substrate a substantially conformal tunnel layer before the ferroelectric material layer is formed.

32. The method of claim 31, wherein the tunnel layer comprises silicon oxide.

33. The method of claim 30, wherein each word line has a first insulating layer thereon, the step of forming the bit lines comprises forming a plurality of linear second insulating layers and forming two bit lines on two sidewalls of each second insulating layer, and the bit lines are separated from the word lines by the first insulating layer, further comprising, before the ferroelectric material layer is formed,
removing portions of the first insulating layer using the second insulating layers and the bit lines as a mask; and
forming over the substrate a substantially conformal first tunnel layer.

34. The method of claim 33, wherein the ferroelectric material layer fills up gaps between the bit lines.

35. The method of claim 33, wherein the first tunnel layer comprises silicon oxide.

36. The method of claim 33, wherein the step of forming two bit lines on the two sidewalls of each second insulating layer comprises:
forming over the substrate a substantially conformal conductive layer; and
performing anisotropic etching to the conductive layer.

37. The method of claim 33, further comprising, after the ferroelectric material layer is formed,
forming on the ferroelectric material layer a second tunnel layer; and
forming on the second tunnel layer a plurality of upper-level word lines extending in the first direction.

38. The method of claim 37, wherein the second tunnel layer comprises SiO.

39. The method of claim 30, wherein the ferroelectric material comprises BiFeO₃.

40. The method of claim 30, wherein the ferroelectric material layer is formed through metal-organic chemical vapor deposition (MOCVD).
